(19) United States
(12) Patent Application Publication
(10) Pub. No.: US 2025/0105078 A1
(43) Pub. Date: Mar. 27, 2025

(54) SEMICONDUCTOR DEVICE AND MANUFACTURING METHOD THEREOF

(71) Applicants: Kabushiki Kaisha Toshiba, Tokyo (JP); Toshiba Electronic Devices & Storage Corporation, Tokyo (JP)

(72) Inventor: Shunsuke SHOJI, Nomi Ishikawa (JP)

(21) Appl. No.: 18/635,862

(22) Filed: Apr. 15, 2024

(30) Foreign Application Priority Data
Sep. 21, 2023 (JP) 2023-156469

(51) Int. Cl. H01L 23/31; H01L 21/782; H01L 23/29; H01L 29/739; H01L 29/78

(52) U.S. Cl. CPC H01L 23/3135; H01L 23/296; H01L 23/3121; H10D 12/411; H10D 30/658; H10D 89/011

(57) ABSTRACT

A semiconductor device according to an embodiment includes: a semiconductor part including a first main surface and a second main surface on an opposite side of the first main surface; a surface structure part provided on the first main surface, the surface structure part including a first electrode; a second electrode provided on the second main surface; a first protective resin film configured to cover an upper surface of the surface structure part; and a second protective resin film connected to the first protective resin film and configured to cover a side surface of the surface structure part.

### CROSS-REFERENCE TO RELATED APPLICATIONS

This application is based upon and claims the benefit of priority from the prior Japanese Patent Application No. 2023-156469, filed on Sep. 21, 2023; the entire contents of which are incorporated herein by reference.

### FIELD

Embodiments described herein relate generally to a semiconductor device and a manufacturing method thereof.

### BACKGROUND

In a semiconductor device such as a metal oxide semiconductor field effect transistor (MOSFET), in order to protect a metal portion such as a wiring layer and an electrode, the metal portion is covered with a protective resin film such as a polyimide resin.

In order to prevent occurrence of chipping and dust in a dicing process of the semiconductor device, the protective resin film on a dicing line is usually removed in advance by etching or the like. However, there is a case in which the protective resin film covering the side surface of the metal portion is also removed due to positional deviation of exposure in a photolithography process. In such a case, foreign substances such as moisture and ions that have entered the semiconductor device easily reach the metal portion, which causes deterioration in reliability of the semiconductor device.

### BRIEF DESCRIPTION OF THE DRAWINGS

FIG. 1 is a schematic cross-sectional view of a peripheral portion of a semiconductor device according to an embodiment;

FIG. 2 is a cross-sectional view illustrating details of the peripheral portion in the semiconductor device according to the embodiment;

FIG. 3 is a flowchart illustrating an example of a manufacturing process of the semiconductor device according to the embodiment;

FIG. 4A is a cross-sectional view illustrating the example of the manufacturing process of the semiconductor device according to the embodiment;

FIG. 4B is a cross-sectional view illustrating the example of the manufacturing process of the semiconductor device according to the embodiment, following FIG. 4A;

FIG. 4C is a cross-sectional view illustrating the example of the manufacturing process of the semiconductor device according to the embodiment, following FIG. 4B;

FIG. 4D is a cross-sectional view illustrating the example of the manufacturing process of the semiconductor device according to the embodiment, following FIG. 4C;

FIG. 4E is a cross-sectional view illustrating the example of the manufacturing process of the semiconductor device according to the embodiment, following FIG. 4D; and

FIG. 5 is a cross-sectional view illustrating details of a peripheral portion in a semiconductor device according to a modification.

### DETAILED DESCRIPTION

A semiconductor device according to an embodiment includes: a semiconductor part including a first main surface and a second main surface on an opposite side of the first main surface; a surface structure part provided on the first main surface, the surface structure part including a first electrode; a second electrode provided on the second main surface; a first protective resin film configured to cover an upper surface of the surface structure part; and a second protective resin film connected to the first protective resin film and configured to cover a side surface of the surface structure part.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, the same elements as those described in the previous drawings are denoted by the same reference numerals, and a detailed description thereof is appropriately omitted.

For convenience of description, in the stacking direction (thickness direction) of a semiconductor device, a gate wiring layer and a source electrode side are also referred to as “upper”, and a drain electrode side is also referred to as “lower”. However, this expression is used for convenience and is independent of the direction of gravity.

In the following description, notations of n⁺, n, and n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both a p-type impurity and an n-type impurity are contained in each region, these notations represent the relative level of net impurity concentration after these impurities have been compensated. It is noted that, in the following description, an n-type and a p-type may be reversed.

### Semiconductor Device

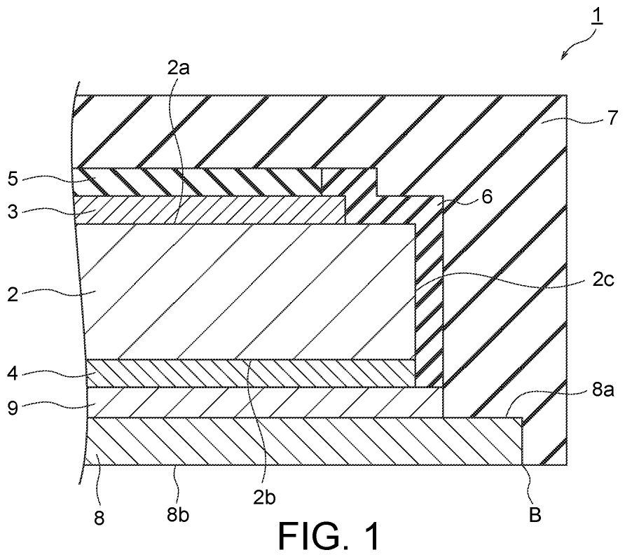

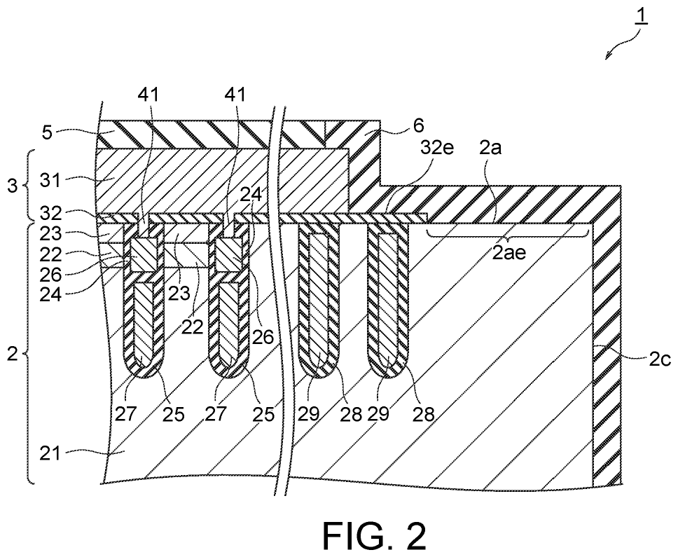

A semiconductor device 1 according to an embodiment will be described with reference to FIGS. 1 and 2. FIG. 1 is a schematic cross-sectional view of a peripheral portion of the semiconductor device 1 according to the embodiment. FIG. 2 is a cross-sectional view illustrating details of the peripheral portion in the semiconductor device 1 according to the embodiment. It is noted that, in FIG. 2, a sealing part 7 is omitted.

Hereinafter, a case in which the semiconductor device 1 is a vertical MOSFET will be described.

As illustrated in FIG. 1, the semiconductor device 1 includes a semiconductor part 2, a surface structure part 3, a drain electrode 4, a protective resin film 5, an additional protective resin film 6, the sealing part 7, a die pad 8, and a bonding material 9.

The semiconductor part 2 includes an upper surface (first main surface) 2a, a lower surface (second main surface) 2b on the opposite side of the upper surface 2a, and a side surface 2c. Although described in detail later, the semiconductor part 2 includes semiconductor regions such as a drift region, a base region, a source region, and a drain region. It is noted that, for convenience of description, the upper surface 2a, the lower surface 2b, and the side surface 2c of the semiconductor part 2 are substantially planar shapes, but this does not limit the shape of the semiconductor part 2.

The semiconductor part 2 may be an epitaxial layer, a semiconductor substrate, or a semiconductor substrate and an epitaxial layer disposed on the semiconductor substrate. In the present embodiment, the semiconductor part 2 is silicon (Si). In this case, for example, arsenic (As), phosphorus (P), or antimony (Sb) is used as the n-type impurity, and for example, boron (B) is used as the p-type impurity. It is noted that the semiconductor part 2 may be made of a compound semiconductor such as silicon carbide (SiC) or gallium nitride (GaN).

The surface structure part 3 is provided on the upper surface 2a of the semiconductor part 2. In the present embodiment, as illustrated in FIG. 2, the surface structure part 3 includes a gate wiring layer 31 and an interlayer insulating film 32. It is noted that, although not illustrated in the drawing, the surface structure part 3 may include a source electrode, a wiring, and the like.

The gate wiring layer 31 is a wiring layer provided on the upper surface 2a of the semiconductor part 2 in order to electrically connect gate electrodes 26 described later to each other. The gate wiring layer 31 is made of, for example, metal such as copper, titanium, tungsten, or aluminum. That is, the gate wiring layer 31 is an example of a metal portion in the semiconductor device 1. The gate wiring layer 31 is an example of a first electrode in the claims.

The interlayer insulating film 32 is provided between the semiconductor part 2 and the gate wiring layer 31. The gate wiring layer 31 is electrically insulated from the semiconductor part 2 by the interlayer insulating film 32. On the other hand, the gate wiring layer 31 is electrically connected to the gate electrode 26 to be described later via a contact plug 41 filling an opening provided in the interlayer insulating film 32 and the gate insulating film 24 described later. It is noted that the contact plug 41 is made of metal such as copper, titanium, tungsten, or aluminum, polysilicon containing the p-type impurity or the n-type impurity, or the like.

In the present embodiment, as illustrated in FIG. 2, the upper surface 2a of the semiconductor part 2 has an end part 2ae at which the surface structure part 3 is not provided. More specifically, the upper surface 2a of the semiconductor part 2 has the end part 2ae that is not covered with the interlayer insulating film 32. The end part 2ae is a margin region provided to avoid contact between a dicing blade and the interlayer insulating film 32 due to positional deviation of the dicing blade during a dicing process.

In the present embodiment, as illustrated in FIG. 2, an end part 32e of the interlayer insulating film 32 is not covered with the gate wiring layer 31, but is covered with the additional protective resin film 6 to be described later. It is noted that the present invention is not limited thereto, and the end part 32e of the interlayer insulating film 32 may be covered with the gate wiring layer 31.

As illustrated in FIG. 1, the drain electrode 4 is provided on the lower surface 2b of the semiconductor part 2. The drain electrode 4 is an electrode that functions as a drain electrode of the MOSFET. The drain electrode 4 is made of, for example, metal such as copper, titanium, tungsten, or aluminum. The drain electrode 4 is an example of a second electrode in the claims.

The protective resin film 5 is provided so as to cover the upper surface of the surface structure part 3. In the present embodiment, as illustrated in FIG. 2, the protective resin film 5 is provided so as to cover the upper surface of the gate wiring layer 31. The protective resin film 5 is an example of a first protective resin film in the claims.

On the other hand, the protective resin film 5 does not cover the side surface of the surface structure part 3. In the present embodiment, as shown in FIG. 2, the protective resin film 5 does not cover the side surface of the gate wiring layer 31 included in the surface structure part 3.

The material of the protective resin film 5 is, for example, a polyimide resin. It is noted that the material of the protective resin film 5 may be a polyamide resin, a polyolefin resin, a polybenzoxazole resin, a silicon resin, or the like.

The additional protective resin film 6 is provided so as to cover the side surface of the surface structure part 3 that is not covered with the protective resin film 5. In the present embodiment, as shown in FIG. 2, the additional protective resin film 6 covers the side surface of the gate wiring layer 31 that is not covered with the protective resin film 5. Further, the additional protective resin film 6 is connected to the protective resin film 5. As described above, the protective resin film 5 does not cover an end part including a corner part and a side part of the surface structure part 3, and the additional protective resin film 6 covers the end part. The additional protective resin film 6 is an example of a second protective resin film in the claims.

Furthermore, in the present embodiment, the additional protective resin film 6 further covers the end part 2ae of the upper surface 2a of the semiconductor part 2 and the side surface 2c of the semiconductor part 2 in addition to the side surface of the surface structure part 3. That is, as shown in FIG. 1, the additional protective resin film 6 is also provided between the semiconductor part 2 and the sealing part 7. Further, in the present embodiment, as illustrated in FIG. 1, the additional protective resin film 6 covers up to a bottom part of the side surface 2c of the semiconductor part 2.

The material of the additional protective resin film 6 is, for example, a polyimide resin. It is noted that the material of the additional protective resin film 6 may be a polyamide resin, a polyolefin resin, a polybenzoxazole resin, a silicon resin, or the like. The material of the additional protective resin film 6 may be the same as or different from the material of the protective resin film 5.

As illustrated in FIG. 1, the sealing part 7 is provided so as to bury at least the semiconductor part 2, the surface structure part 3, the protective resin film 5, and the additional protective resin film 6. In the present embodiment, the sealing part 7 further buries the drain electrode 4 and the bonding material 9. The material of the sealing part 7 is, for example, an epoxy resin.

It is noted that, when the material of the sealing part 7 is an epoxy resin, adhesion between the additional protective resin film 6 and the sealing part 7 can be improved by using a polyimide resin as the material of the additional protective resin film 6.

The die pad 8 is a die pad (bed) in the semiconductor device 1, and the semiconductor part 2 and the like are mounted on the die pad 8. The die pad 8 is obtained by, for example, punching a metal plate. The material of the die pad 8 is not particularly limited, and is, for example, copper, a 42% Ni—Fe alloy (42 alloy), or the like.

As illustrated in FIG. 1, the die pad 8 includes a die pad upper surface (first die pad main surface) 8a and a die pad lower surface (second die pad main surface) 8b on the opposite side of the die pad upper surface 8a, and the drain electrode 4 is bonded to the die pad upper surface 8a with the bonding material 9 interposed therebetween. In the present embodiment, the bonding material 9 is a conductive material such as solder, and the die pad 8 is electrically connected to the drain electrode 4 with the bonding material 9 interposed therebetween.

In the present embodiment, the die pad upper surface 8a and the side surface of the die pad 8 are covered with the sealing part 7. On the other hand, the die pad lower surface 8b of the die pad 8 is not covered with the sealing part 7 and is exposed. That is, in the semiconductor device 1, a boundary B between the sealing part 7 and the die pad 8 is exposed. Therefore, foreign substances such as moisture and ions may enter the semiconductor device 1 from the boundary B. However, since the additional protective resin film 6 covering the side surface of the gate wiring layer 31 is provided, it is possible to prevent the foreign substances that have entered the semiconductor device 1 from the boundary B from reaching the side surface of the gate wiring layer 31 which is a metal portion.

It is noted that a sealing form by the sealing part 7 is not limited to a sealing form illustrated in FIG. 1. For example, the sealing part 7 may further cover a part of the die pad lower surface 8b of the die pad 8 in addition to the die pad upper surface 8a and the side surface of the die pad 8. Alternatively, the sealing part 7 covers the die pad upper surface 8a of the die pad 8, but may not cover at least a part of the side surface of the die pad 8. In any sealing form, since a boundary between the sealing part 7 and the die pad 8 is exposed, there is a possibility that foreign substances such as moisture or ions enter the semiconductor device 1 from the boundary. However, according to the present embodiment, since the additional protective resin film 6 covering the side surface of the gate wiring layer 31 is provided, it is possible to prevent the foreign substances that have entered the semiconductor device 1 from the boundary from reaching the side surface of the gate wiring layer 31.

Next, details of the semiconductor part 2 in the present embodiment will be described with reference to FIG. 2.

As illustrated in FIG. 2, the semiconductor part 2 includes a drift region 21, a base region 22, a source region 23, a drain region (not illustrated), a gate insulating film 24, a field plate insulating film 25, a gate electrode 26, a field plate 27, a field plate insulating film 28, and a field plate 29.

The drift region 21 is a semiconductor region that functions as a drift region of the MOSFET. The drift region 21 is disposed on the drain region (not illustrated) (above the drain electrode 4). The drift region 21 is, for example, an n-type semiconductor region. The n-type impurity concentration of the drift region 21 is, for example, 1×10¹⁵ cm⁻³ or more and 2×10¹⁶ cm⁻³ or less.

The base region 22 is a semiconductor region that functions as a base region of the MOSFET. In the left-and-right direction, the base region 22 is disposed at a position sandwiched between the gate electrodes 26 via the gate insulating film 24, and in the upward-and-downward direction, the base region 22 is disposed on the drift region 21. When a voltage is applied to the gate electrode 26, a channel is formed in the base region 22, and carriers flow between the drift region 21 and the source region 23. The base region 22 is, for example, a p-type semiconductor region. The p-type impurity concentration of the base region 22 is, for example, 1×10¹⁶ cm⁻³ or more and 1×10²⁰ cm⁻³ or less.

The source region 23 is a semiconductor region that functions as a source region of the MOSFET. The source region 23 is electrically connected to a source electrode (not illustrated). The source region 23 is disposed between the base region 22 and the interlayer insulating film 32. The source region 23 is, for example, an n⁺-type semiconductor region. The n-type impurity concentration of the source region 23 is, for example, 1×10¹⁸ cm⁻³ or more and 1×10²² cm⁻³ or less.

Although not illustrated in the drawing, the drain region functioning as a drain region of the MOSFET is disposed between the drift region 21 and the drain electrode 4. The drain region is, for example, an n⁺-type semiconductor region. The n-type impurity concentration of the drain region is, for example, 1×10¹⁸ cm⁻³ or more and 1×10²¹ cm⁻³ or less.

As illustrated in FIG. 2, the semiconductor part 2 is provided with a plurality of gate insulating films 24 and a plurality of field plate insulating films 25 respectively disposed below the plurality of gate insulating films 24. Each of the field plate insulating films 25 is provided so as to reach the drift region 21. The gate insulating film 24 and the field plate insulating film 25 are made of a dielectric that covers sidewalls of a plurality of trenches provided on the upper surface 2a of the semiconductor part 2. Each of the gate insulating film 24 and the field plate insulating film 25 is made of a dielectric such as silicon oxide or silicon nitride. It is noted that, as illustrated in FIG. 2, the gate insulating film 24 disposed between the gate electrode 26 and the base region 22 is thinner than the field plate insulating film 25 disposed between the field plate 27 and the drift region 21.

The gate electrode 26 is provided in each of the gate insulating films 24. The gate electrode 26 is an electrode that functions as a gate electrode of the MOSFET. In the present embodiment, the upper end of the gate electrode 26 is located higher than the upper end of the base region 22, and the lower end of the gate electrode 26 is located lower than the lower end of the base region 22. The gate electrode 26 is disposed adjacent to (facing) the base region 22 with the gate insulating film 24 interposed therebetween.

The gate electrode 26 is made of, for example, polysilicon containing the p-type impurity or the n-type impurity, or the like. It is noted that the gate electrode 26 may be made of metal such as copper, titanium, tungsten, or aluminum. The gate electrode 26 is electrically connected to the gate wiring layer 31 via the contact plug 41 filling the opening provided in the interlayer insulating film 32 and the gate insulating film 24. The gate electrode 26 is electrically insulated from the semiconductor part 2 by the gate insulating film 24.

The field plate 27 is provided in each of the field plate insulating films 25. The field plate 27 is made of polysilicon containing the p-type impurity or the n-type impurity, or the like. Each field plate 27 is electrically connected to a source electrode (not illustrated). By providing such a field plate 27, a depletion layer extends from the field plate insulating film 25 to the drift region 21 by a voltage applied to a space between the source electrode and the drain electrode 4 when the MOSFET is in the off state. This depletion layer is connected to a depletion layer extending from the adjacent field plate insulating film 25, thereby making it possible to improve a withstand voltage of the semiconductor device 1.

A plurality of field plates 29 are provided on a peripheral edge part of the semiconductor part 2 with a plurality of field plate insulating films 28 interposed therebetween. In the present embodiment, as illustrated in FIG. 2, two field plate insulating films 28 are provided, and the field plates 29 are respectively provided in the field plate insulating films 28. That is, in the present embodiment, the two field plates 29 are provided in the peripheral edge part of the semiconductor part 2. It is noted that the number of the field plates 29 may be one or three or more. The field plate insulating film 28 is made of a dielectric that covers sidewalls of a plurality of field plate trenches provided on the upper surface 2a of the semiconductor part 2. The field plate insulating film 28 is made of a dielectric such as silicon oxide or silicon nitride.

In the present embodiment, as illustrated in FIG. 2, a depth from the upper surface 2a of the semiconductor part 2 to the lower end of the field plate insulating film 28 is substantially the same as a depth from the upper surface 2a of the semiconductor part 2 to the lower end of the field plate insulating film 25. It is noted that the present invention is not limited thereto, and the depth from the upper surface 2a of the semiconductor part 2 to the lower end of the field plate insulating film 28 may be different from the depth from the upper surface 2a of the semiconductor part 2 to the lower end of the field plate insulating film 25.

Each field plate 29 is electrically connected to the source electrode. By providing the field plate 29, concentration of a reverse electric field between the gate wiring layer 31 and the drain electrode 4 can be alleviated, thereby making it possible to improve the withstand voltage of the semiconductor device 1.

Although the configuration example of the semiconductor part 2 according to the present embodiment has been described above, the configuration of the semiconductor part 2 is not limited to the above-described configuration, and may take any configuration according to the type and function of the semiconductor device 1. The semiconductor device 1 is not limited to the MOSFET, and may be, for example, an insulated gate bipolar transistor (IGBT), a diode, a light emitting diode, or a semiconductor laser. In the case of the IGBT, a conduction form of the drain region of the semiconductor part 2 may be changed.

As described above, the semiconductor device 1 according to the embodiment is provided with the additional protective resin film 6 that is connected to the protective resin film 5 and covers the side surface of the surface structure part 3 that is not covered with the protective resin film 5. As a result, it is possible to prevent foreign substances that have entered the semiconductor device 1 from the boundary B between the sealing part 7 and the die pad 8 from reaching the gate wiring layer 31 of the surface structure part 3. Therefore, for example, the gate wiring layer 31 can be prevented from being oxidized (anodized or the like) by the foreign substances entering the semiconductor device 1. Therefore, reliability of the semiconductor device 1 can be improved.

In the present embodiment, the additional protective resin film 6 covers the end part 2ae of the upper surface 2a of the semiconductor part 2 and the side surface 2c of the semiconductor part 2 in addition to the side surface of the surface structure part 3. As a result, it is possible to further prevent the foreign substances that have entered the semiconductor device 1 from the boundary B between the sealing part 7 and the die pad 8 from reaching the gate wiring layer 31.

Additionally, in the present embodiment, the additional protective resin film 6 covers the bottom part of the side surface 2c of the semiconductor part 2. As a result, it is possible to further prevent the foreign substances that have entered the semiconductor device 1 from the boundary B between the sealing part 7 and the die pad 8 from reaching the gate wiring layer 31.

It is noted that a source electrode (an emitter electrode when the semiconductor device 1 is the IGBT) may be provided instead of the gate wiring layer 31 at the position of the gate wiring layer 31 of the surface structure part 3 illustrated in FIG. 2. The source electrode is also an example of a metal portion in the semiconductor device 1. The source electrode is usually used as a cathode, but may also be used as an anode, for example, in the case of a switching operation of the MOSFET or the like. In such a case as well, by providing the additional protective resin film 6, it is possible to prevent oxidation (anodic oxidation or the like) of the source electrode due to foreign substances that have entered the semiconductor device 1.

### Manufacturing Method of Semiconductor Device

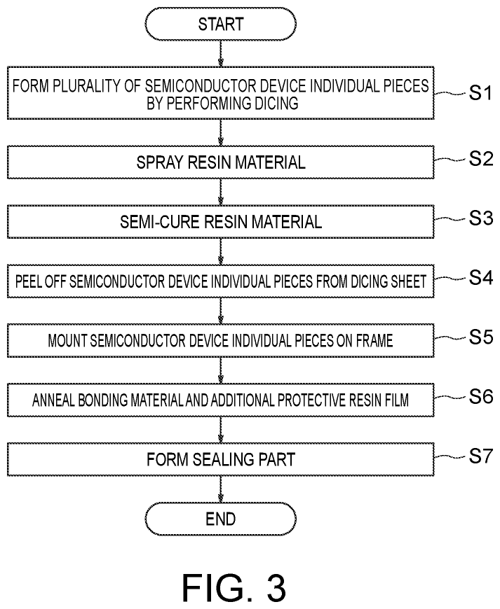

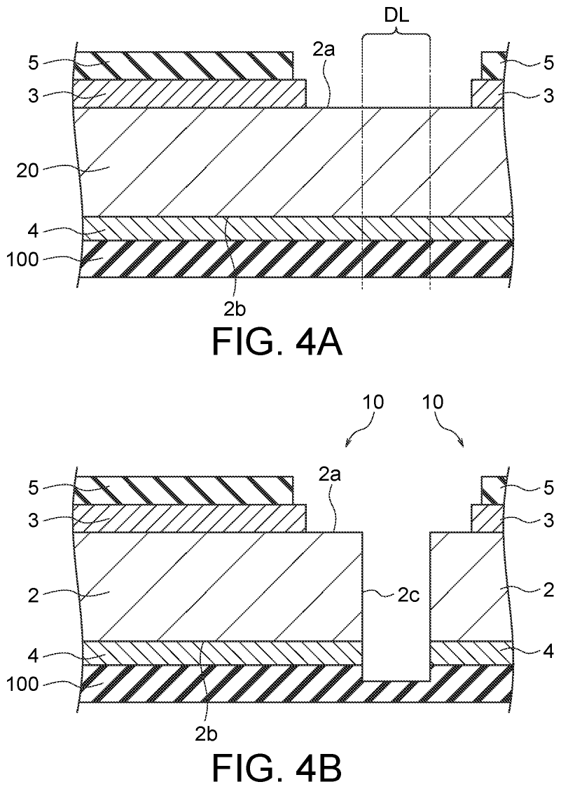

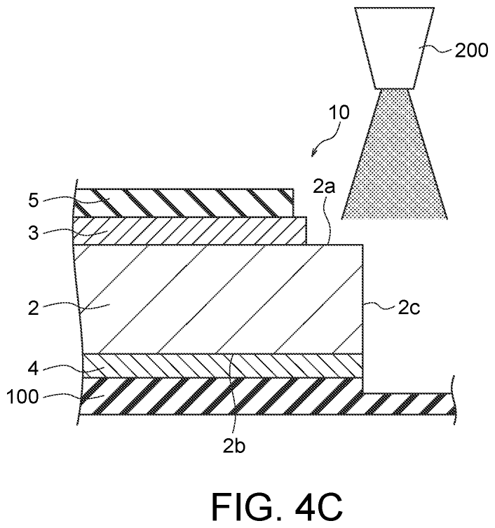

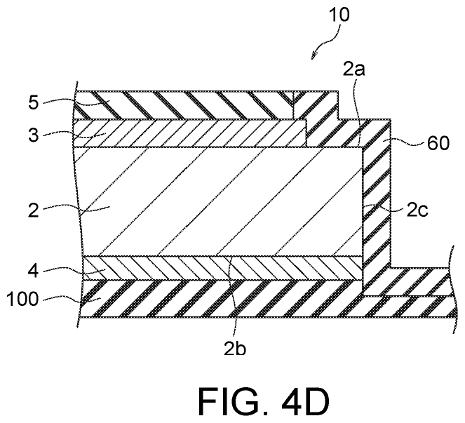

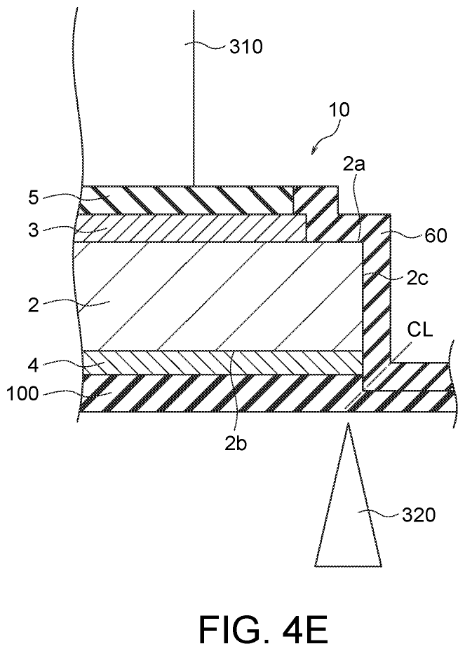

Next, an example of a manufacturing method of the semiconductor device 1 according to the present embodiment will be described with reference to a flowchart in FIG. 3 and process cross-sectional views in FIGS. 4A to 4E.

First, dicing is performed to form a plurality of semiconductor device individual pieces 10 (step S1). More specifically, first, as illustrated in FIG. 4A, a semiconductor wafer 20 including the upper surface (first main surface) 2a and the lower surface (second main surface) 2b on the opposite side of the upper surface 2a is prepared. A plurality of surface structure parts 3 including a gate wiring layer and a plurality of protective resin films 5 covering the surface structure part 3 are formed on the upper surface 2a of the semiconductor wafer 20, and the drain electrode 4 is formed on the lower surface 2b of the semiconductor wafer 20. Further, although not illustrated in the drawing, semiconductor regions such as the drift region 21, the base region 22, the source region 23, and the drain region, the gate electrode 26, the field plates 27 and 29, and the like are formed inside the semiconductor wafer 20.

The semiconductor wafer 20 before dicing illustrated in FIG. 4A is formed by, for example, the following process. The plurality of surface structure parts 3 including the gate wiring layer are formed on the upper surface 2a of the semiconductor wafer 20 so as to avoid a dicing line DL, and the drain electrode 4 is formed on the lower surface 2b of the semiconductor wafer 20. Thereafter, a protective resin layer is formed on the upper surface 2a of the semiconductor wafer 20 so as to bury the plurality of surface structure parts 3, and a resist film (not illustrated) covering the upper surface of the formed protective resin layer is formed.

Thereafter, the resist film on the dicing line DL is removed by photolithography. Thereafter, by using the patterned resist film as a mask, the protective resin layer in the dicing line DL is removed by etching to form a plurality of protective resin films 5. It is noted that, when the resist film is patterned by photolithography, the plurality of protective resin films 5 may be formed by removing the protective resin layer immediately below the opening of the resist film together with the resist film. Thereafter, the resist film is peeled off from the upper surface of the protective resin film 5, thereby forming the semiconductor wafer 20 illustrated in FIG. 4A.

In the above process, for example, the end part of the surface structure part 3 may not be covered with the protective resin film 5 after etching of the protective resin layer due to positional deviation of exposure in photolithography. FIG. 4A illustrates a case in which the end part of the surface structure part 3 is not covered with the protective resin film 5.

Next, the semiconductor wafer 20 is fixed to a dicing sheet 100 such that the lower surface 2b of the semiconductor wafer 20 faces the dicing sheet 100. In the present embodiment, the drain electrode 4 is fixed so as to be in contact with the dicing sheet 100.

Thereafter, the semiconductor wafer 20 is diced along the dicing line DL illustrated in FIG. 4A to divide the semiconductor wafer 20 into the plurality of semiconductor parts 2. In the present embodiment, dicing is performed until the dicing sheet 100 is reached. As a result, as illustrated in FIG. 4B, a plurality of semiconductor device individual pieces 10 are formed. More specifically, each semiconductor device individual piece 10 includes the semiconductor part 2 including the upper surface 2a and the lower surface 2b, the surface structure part 3 provided on the upper surface 2a of the semiconductor part 2 and formed to include the gate wiring layer 31, the drain electrode 4 provided on the lower surface 2b of the semiconductor part 2, and the protective resin film 5 covering the upper surface of the surface structure part 3, and is fixed to the dicing sheet 100. It is noted that, in the following description, the semiconductor device individual piece 10 on the right side in FIG. 4B is omitted.

Next, as shown in FIG. 4C, a resin material is sprayed onto the side surface of the surface structure part 3 (step S2). In the present embodiment, the resin material is sprayed onto the side surface of the protective resin film 5, the side surface of the surface structure part 3, the end part of the upper surface 2a of the semiconductor part 2, and the side surface 2c of the semiconductor part 2 using a spray 200 such as an inkjet spray or an aerosol spray. The resin material is, for example, a polyimide resin. It is noted that the resin material may be a silicon resin, a polybenzoxazole resin, a polyamide resin, a polyolefin resin, or the like. Further, as the resin material, a precursor of polyimide may be used. In the case of a resin material soluble in an organic solvent, a varnish-like resin material in which the resin material is dissolved in the organic solvent may be sprayed.

Next, hot air or warm air is applied to the sprayed resin material to semi-cure the resin material (step S3). As a result, as illustrated in FIG. 4D, an additional protective resin film 60 that is connected to the protective resin film 5 and covers the side surface of the surface structure part 3, the end part of the upper surface 2a of the semiconductor part 2, and the side surface 2c of the semiconductor part 2 is formed. It is noted that the resin material may be completely cured by this process. Further, when the varnish-like resin material is sprayed, the resin material may be semi-cured or completely cured by applying air at room temperature or by natural drying without applying air.

Next, as illustrated in FIG. 4E, the upper surface of the protective resin film 5 in the semiconductor device individual piece 10 is attracted by a collet 310, and the semiconductor device individual piece 10 is pushed up from the lower surface of the dicing sheet 100 by a push-up pin 320 in a state in which the dicing sheet 100 is stretched. As a result, the semiconductor device individual piece 10 is peeled off from the dicing sheet 100 (step S4). At this time, the additional protective resin film 60 is cut by a cutting line CL.

Thereafter, although not illustrated in the drawing, the semiconductor device individual piece 10 is mounted on the die pad 8 with a bonding material (cream solder or the like) interposed therebetween (step S5).

Thereafter, the bonding material and the additional protective resin film 60 are annealed (step S6). This process is performed to cure the bonding material, but at the same time, the additional protective resin film 60 can also be cured. The additional protective resin film 60 is cured to become the additional protective resin film 6.

Thereafter, the sealing part 7 in which the semiconductor part 2, the surface structure part 3, the protective resin film 5, and the additional protective resin film 6 are buried is formed (step S7).

Through the above-described processes, the semiconductor device 1 according to the embodiment can be manufactured. According to the manufacturing method of the semiconductor device 1 according to the embodiment, even in a case where the end part of the surface structure part 3 is not covered with the protective resin film 5 due to positional deviation of exposure in the photolithography process, for example, it is possible to manufacture the semiconductor device 1 in which the surface structure part 3 is covered without a gap at a peripheral portion by forming the additional protective resin film 6.

The additional protective resin film 6 is formed by spraying the resin material to the end part of the surface structure part 3 using an inkjet spray or an aerosol spray. Thereby, the additional protective resin film 6 can be easily and locally formed at the end part of the surface structure part 3.

Further, before the semiconductor device individual piece 10 is peeled off from the dicing sheet 100, the additional protective resin film 60 is semi-cured. Accordingly, when the dicing sheet 100 is peeled off, the additional protective resin film 60 can be cut along the appropriate cutting line CL.

### Modification

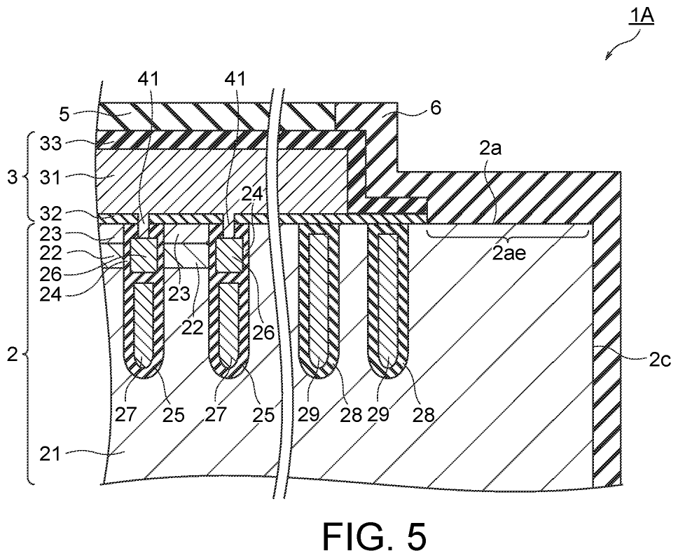

Next, a semiconductor device 1A according to a modification of the embodiment will be described with reference to FIG. 5. FIG. 5 is a cross-sectional view illustrating details of a peripheral portion in the semiconductor device 1A according to the present modification. It is noted that, similarly to FIG. 2, the sealing part 7 is omitted in FIG. 5.

One of the differences between the present modification and the above-described embodiment is presence of a protective film 33. Hereinafter, the present modification will be described focusing on differences from the above-described embodiment.

As illustrated in FIG. 5, the surface structure part 3 of the semiconductor device 1A according to the present modification further includes the protective film 33 made of oxide or nitride. The protective film 33 is provided between the gate wiring layer 31 and the protective resin film 5 and between the gate wiring layer 31 and the additional protective resin film 6. That is, the protective film 33 covers the upper surface and the side surface of the gate wiring layer 31. The protective film 33 is, for example, silicon oxide in the case of oxide, and is, for example, silicon nitride in the case of nitride.

In the present modification, the additional protective resin film 6 covers the side surface of the protective film 33 that is not covered with the protective resin film 5. Since the gate wiring layer 31 included in the surface structure part 3 is covered with the protective film 33 as described above, foreign substances that have entered the semiconductor device 1A from a boundary between the sealing part 7 and the die pad 8 are prevented from reaching the side surface of the gate wiring layer 31. However, for example, a crack may occur in the protective film 33 due to a thermal cycle when the semiconductor device 1A is driven. In this case, the foreign substances that have entered the semiconductor device 1A from the boundary between the sealing part 7 and the die pad 8 may pass through the crack and reach the side surface of the gate wiring layer 31.

In the present modification, since the additional protective resin film 6 covering the protective film 33 is provided, even when the crack occurs in the protective film 33, it is possible to prevent the foreign substances that have entered the semiconductor device 1A from the boundary between the sealing part 7 and the die pad 8 from reaching the side surface of the gate wiring layer 31. As a result, reliability of the semiconductor device 1A can be further improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

### Supplementary Note 1

A semiconductor device including:
a semiconductor part including a first main surface and a second main surface on an opposite side of the first main surface;
a surface structure part provided on the first main surface, the surface structure part including a first electrode;
a second electrode provided on the second main surface;
a first protective resin film configured to cover an upper surface of the surface structure part; and
a second protective resin film connected to the first protective resin film and configured to cover a side surface of the surface structure part.

### Supplementary Note 2

The semiconductor device according to supplementary note 1, in which the second protective resin film covers a side surface of the first electrode.

### Supplementary Note 3

The semiconductor device according to supplementary note 1 or 2, in which the surface structure part further includes a protective film made of oxide or nitride and provided between the first electrode and the first protective resin film and between the first electrode and the second protective resin film.

### Supplementary Note 4

The semiconductor device according to any one of supplementary notes 1 to 3, in which the second protective resin film further covers a side surface of the semiconductor part.

### Supplementary Note 5

The semiconductor device according to supplementary note 4, in which the second protective resin film covers up to a bottom part of the side surface of the semiconductor part.

### Supplementary Note 6

The semiconductor device according to any one of supplementary notes 1 to 5, in which the surface structure part further includes an interlayer insulating film provided between the semiconductor part and the first electrode.

### Supplementary Note 7

The semiconductor device according to any one of supplementary notes 1 to 6, in which the first protective resin film contains a polyimide resin, a polyamide resin, a polyolefin resin, a polybenzoxazole resin, or a silicon resin.

### Supplementary Note 8

The semiconductor device according to any one of supplementary notes 1 to 7, in which the second protective resin film contains a polyimide resin, a polyamide resin, a polyolefin resin, a polybenzoxazole resin, or a silicon resin.

### Supplementary Note 9

The semiconductor device according to any one of supplementary notes 1 to 8, in which a material of the second protective resin film is the same as a material of the first protective resin film.

### Supplementary Note 10

The semiconductor device according to any one of supplementary notes 1 to 8, in which a material of the second protective resin film is different from a material of the first protective resin film.

### Supplementary Note 11

The semiconductor device according to any one of supplementary notes 1 to 10, in which the surface structure part is not provided at an end part of the first main surface of the semiconductor part, and the second protective resin film covers the end part.

### Supplementary Note 12

The semiconductor device according to any one of supplementary notes 1 to 11, further including:
a die pad including a first die pad main surface and a second die pad main surface on an opposite side of the first die pad main surface, in which the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

### Supplementary Note 13

The semiconductor device according to any one of the supplementary notes 1 to 12, in which the semiconductor device is a MOSFET or an IGBT.

### Supplementary Note 14

The semiconductor device according to supplementary note 13, in which the first electrode is a gate wiring layer.

### Supplementary Note 15

A manufacturing method of a semiconductor device, the manufacturing method including:
preparing a semiconductor device individual piece fixed to a dicing sheet, the semiconductor device individual piece including a semiconductor part including a first main surface and a second main surface, a surface structure part provided on the first main surface, the surface structure part including a first electrode, a second electrode provided on the second main surface, and a first protective resin film covering an upper surface of the surface structure part;
forming a second protective resin film connected to the first protective resin film and configured to cover a side surface of the surface structure part;
peeling off the semiconductor device individual piece from the dicing sheet;
mounting the semiconductor device individual piece on a die pad with a bonding material interposed therebetween;
annealing the bonding material and the second protective resin film; and
forming a sealing part configured to bury the semiconductor part, the surface structure part, the first protective resin film, and the second protective resin film.

### Supplementary Note 16

The manufacturing method of a semiconductor device according to supplementary note 15, in which the formation of the second protective resin film is performed by spraying a resin material onto the side surface of the surface structure part using an inkjet spray or an aerosol spray.

### Supplementary Note 17

The manufacturing method of a semiconductor device according to supplementary note 15 or 16, in which the second protective resin film is semi-cured before the semiconductor device individual piece is peeled off from the dicing sheet.

1. A semiconductor device comprising:
a semiconductor part including a first main surface and a second main surface on an opposite side of the first main surface;
a surface structure part provided on the first main surface, the surface structure part including a first electrode;
a second electrode provided on the second main surface;
a first protective resin film configured to cover an upper surface of the surface structure part; and
a second protective resin film connected to the first protective resin film and configured to cover a side surface of the surface structure part.

2. The semiconductor device according to claim 1, wherein the second protective resin film covers a side surface of the first electrode.

3. The semiconductor device according to claim 2, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

4. The semiconductor device according to claim 1, wherein the surface structure part further includes a protective film made of oxide or nitride and provided between the first electrode and the first protective resin film and between the first electrode and the second protective resin film.

5. The semiconductor device according to claim 4, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

6. The semiconductor device according to claim 1, wherein the second protective resin film further covers a side surface of the semiconductor part.

7. The semiconductor device according to claim 6, wherein the second protective resin film covers up to a bottom part of the side surface of the semiconductor part.

8. The semiconductor device according to claim 7, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

9. The semiconductor device according to claim 6, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

10. The semiconductor device according to claim 1, wherein the second protective resin film contains a polyimide resin, a polyamide resin, a polyolefin resin, a polybenzoxazole resin, or a silicon resin.

11. The semiconductor device according to claim 10, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

12. The semiconductor device according to claim 1, wherein the surface structure part is not provided at an end part of the first main surface of the semiconductor part, and the second protective resin film covers the end part.

13. The semiconductor device according to claim 12, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

14. The semiconductor device according to claim 1, further comprising:
a die pad including a first die pad main surface and a second die pad main surface on an opposite side of the first die pad main surface, wherein the second electrode is bonded to the first die pad main surface with a bonding material interposed therebetween; and
a sealing part configured to bury the semiconductor part, the surface structure part, the first protective resin film, and the second protective resin film, and to expose the second die pad main surface of the die pad.

15. The semiconductor device according to claim 1, wherein the semiconductor device is a MOSFET or an IGBT.

16. The semiconductor device according to claim 15, wherein the first electrode is a gate wiring layer.

17. A manufacturing method of a semiconductor device, the manufacturing method comprising:
preparing a semiconductor device individual piece fixed to a dicing sheet, the semiconductor device individual piece including a semiconductor part including a first main surface and a second main surface, a surface structure part provided on the first main surface, the surface structure part including a first electrode, a second electrode provided on the second main surface, and a first protective resin film covering an upper surface of the surface structure part;
forming a second protective resin film connected to the first protective resin film and configured to cover a side surface of the surface structure part;
peeling off the semiconductor device individual piece from the dicing sheet;
mounting the semiconductor device individual piece on a die pad with a bonding material interposed therebetween;
annealing the bonding material and the second protective resin film; and
forming a sealing part configured to bury the semiconductor part, the surface structure part, the first protective resin film, and the second protective resin film.

18. The manufacturing method of a semiconductor device according to claim 17, wherein the formation of the second protective resin film is performed by spraying a resin material onto the side surface of the surface structure part using an inkjet spray or an aerosol spray.

19. The manufacturing method of a semiconductor device according to claim 18, wherein the second protective resin film is semi-cured before the semiconductor device individual piece is peeled off from the dicing sheet.

20. The manufacturing method of a semiconductor device according to claim 17, wherein the second protective resin film is semi-cured before the semiconductor device individual piece is peeled off from the dicing sheet.
